(19) United States
(12) Patent Application Publication
(10) Pub. No.: US 2024/0021640 A1
(43) Pub. Date: Jan. 18, 2024

(54) PACKAGE STRUCTURE AND MANUFACTURING METHOD THEREOF

(71) Applicant: POWERTECH TECHNOLOGY INC., Hsinchu City (TW)

(72) Inventors: Ching-Wei LIAO, Hsinchu City (TW); Shang-yu CHANG CHIEN, Hsinchu City (TW)

(21) Appl. No.: 18/350,459

(22) Filed: Jul. 11, 2023

(30) Foreign Application Priority Data
Jul. 13, 2022 (TW) 111126362

(51) Int. Cl. H01L 27/146; H01L 21/56; H01L 21/683

(52) U.S. Cl. CPC H01L 27/14627; H01L 27/14685; H01L 27/14636; H01L 21/565; H01L 21/6835

(57) ABSTRACT

A package structure and a manufacturing method thereof are provided. The package structure includes a plurality of micro-lens chips arranged at intervals and a coplanar control layer. The coplanar control layer is configured to encapsulate the plurality of micro-lens chips therein. At least one surface of each of the micro-lens chips is exposed outside the coplanar control layer, and the at least one surface of each of the micro-lens chips is coplanar.

### CROSS REFERENCE TO RELATED APPLICATIONS

This application claims priority to Taiwan Application Serial No. 111126362, filed Jul. 13, 2022, the disclosure of which is incorporated herein by reference.

### FIELD OF DISCLOSURE

The present disclosure relates to the field of semiconductors, in particular to a package structure and a manufacturing method thereof.

### BACKGROUND

In the current application of integrated circuits, a multi-die stack packaging technology or a system-in-package technology can realize an integration of a variety of chips with different functions into a product, thereby forming a lightweight, compact, high-speed, multi-functional, and high-performance product. In a product with an optical sensing function, a plurality of optical sensing chips are generally arranged in a package structure. Each image sensing chip serves as a pixel. With the development of semiconductor technology, how to make multiple parallel image sensing elements exhibit a best optical performance is a research focus and a technical problem to be solved in the current industry.

Accordingly, the present disclosure provides a package structure and a manufacturing method thereof to solve the above technical problems.

### SUMMARY OF DISCLOSURE

The present disclosure provides a package structure and a manufacturing method thereof, which ensure that a plurality of micro-lens chips arranged in parallel exhibit a best optical performance.

In a first aspect, the present disclosure provides a package structure, including a plurality of micro-lens chips and a coplanar control layer. The plurality of micro-lens chips are arranged at intervals. The coplanar control layer is configured to encapsulate the plurality of micro-lens chips therein. At least one surface of each of the micro-lens chips is exposed outside the coplanar control layer, and the at least one surface of each of the micro-lens chips is coplanar.

In some embodiments, each of the micro-lens chips includes a micro-lens array, a plurality of the micro-lens arrays of the plurality of micro-lens chips are exposed outside the coplanar control layer, and a plurality of surfaces of the plurality of the micro-lens arrays are coplanar.

In some embodiments, each of the micro-lens chips includes solder terminals, a plurality of the solder terminals of the plurality of micro-lens chips are exposed outside the coplanar control layer, and a plurality of surfaces of the plurality of solder terminals are coplanar.

In some embodiments, each of the micro-lens chips further includes a plurality of connection terminals connected to the plurality of solder terminals, the plurality of connection terminals of each of the micro-lens chips are exposed outside the coplanar control layer, a horizontal plane formed by the plurality of connection terminals of each of the micro-lens chips is a connection surface of the micro-lens chip, and a plurality of the connection surfaces of the plurality of micro-lens chips are coplanar.

In some embodiments, the solder terminal is a multi-layer structure, the multi-layer structure includes at least a core and an outer layer, and the outer layer directly or indirectly covers the core.

In some embodiments, the package structure further includes a lower redistribution layer, an active device, a dummy die, an encapsulation layer, and an upper redistribution layer. The lower redistribution layer includes a first surface and a second surface opposite to the first surface. The active device is disposed on the first surface of the lower redistribution layer. The dummy die is disposed on the first surface of the lower redistribution layer. The dummy die is laterally adjacent to the active device. The encapsulation layer is disposed on the first surface of the lower redistribution layer, and is configured to encapsulate the active device and the dummy die. The upper redistribution layer is disposed on the encapsulation layer. The upper redistribution layer is electrically connected to the active device and the plurality of solder terminals of the plurality of micro-lens chips.

In some embodiments, the package structure further includes a connection element disposed on the second surface of the lower redistribution layer, and the connection element is a multi-layer structure.

In a second aspect, the present disclosure provides a manufacturing method of a package structure, including:
providing a carrier;
forming a separation layer on the carrier;
disposing a plurality of micro-lens chips arranged at intervals on the separation layer;
forming a coplanar control layer on the separation layer, where the coplanar control layer encapsulates the plurality of micro-lens chips therein; and
removing the carrier by the separation layer, where at least one surface of each of the micro-lens chips is exposed outside the coplanar control layer, and a plurality of the at least one surfaces of the plurality of micro-lens chips are coplanar.

In some embodiments, each of the micro-lens chips includes a micro-lens array, and before the plurality of micro-lens chips are disposed on the separation layer, the manufacturing method further includes: forming a protective film on each of the micro-lens chips, and the protective film covers the micro-lens array.

After removing the carrier, the manufacturing method further includes: removing the protective film. The plurality of micro-lens arrays of the plurality of micro-lens chips are exposed outside the coplanar control layer, and a plurality of surfaces of the plurality of micro-lens arrays are coplanar.

In some embodiments, before removing the carrier, the manufacturing method further includes: forming solder terminals of each of the micro-lens chips. A plurality of the solder terminals of the plurality of micro-lens chips are exposed outside the coplanar control layer, and a plurality of surfaces of the plurality of the solder terminals are coplanar.

In some embodiments, each of the micro-lens chips further includes a plurality of connection terminals connected to the plurality of solder terminals, and the plurality of connection terminals of each of the micro-lens chips are exposed outside the coplanar control layer, a horizontal plane formed by the plurality of connection terminals of each of the micro-lens chips is a connection surface of the micro-lens chip, and a plurality of the connection surfaces of the plurality of micro-lens chips are coplanar.

In some embodiments, the solder terminal is a multi-layer structure, the multi-layer structure includes at least a core and an outer layer, and the outer layer directly or indirectly covers the core.

In some embodiments, the manufacturing method of the package structure further includes:
forming a lower redistribution layer, where the lower redistribution layer includes a first surface and a second surface opposite to the first surface;
forming an active device and a dummy die on the first surface of the lower redistribution layer, where the dummy die is laterally adjacent to the active device;
forming an encapsulation layer on the first surface of the lower redistribution layer, where the encapsulation layer is configured to encapsulate the active device and the dummy die;
forming an upper redistribution layer on the encapsulation layer, where the upper redistribution layer is electrically connected to the active device; and
assembling the plurality of micro-lens chips and the coplanar control layer with the upper redistribution layer, where the upper redistribution layer is electrically connected to the plurality of solder terminals of the plurality of micro-lens chips.

In some embodiments, the manufacturing method of the package structure further includes: forming a connection element on the second surface of the lower redistribution layer. The connection element is a multi-layer structure.

In a third aspect, the present disclosure provides a package structure, including a plurality of micro-lens chips and a coplanar control layer. The plurality of micro-lens chips are arranged at intervals. The coplanar control layer is configured to encapsulate the plurality of micro-lens chips therein. Each of the micro-lens chips includes a lens surface, a connection surface, and a terminal surface, and one of the lens surface, the connection surface, and the terminal surface of each of the micro-lens chips is coplanar.

In some embodiments, each of the micro-lens chips includes a micro-lens array, a plurality of the micro-lens arrays of the plurality of micro-lens chips are exposed outside the coplanar control layer, a horizontal plane formed by outermost endpoints of a plurality of lenses of the micro-lens array of each micro-lens chip is the lens surface of the micro-lens chip, and a plurality of the lens surfaces of the plurality of micro-lens chips are coplanar.

In some embodiments, each of the micro-lens chips includes solder terminals, a plurality of the solder terminals of the plurality of micro-lens chips are exposed outside the coplanar control layer, a horizontal plane formed by outermost endpoints of the plurality of solder terminals of each micro-lens chip is the terminal surface of the micro-lens chip, and a plurality of the terminal surfaces of the plurality of micro-lens chips are coplanar.

In some embodiments, each of the micro-lens chips further includes a plurality of connection terminals connected to the plurality of solder terminals, the plurality of connection terminals of each of the micro-lens chips are exposed outside the coplanar control layer, a horizontal plane formed by the plurality of connection terminals of each micro-lens chip is the connection surface of the micro-lens chip, and a plurality of the connection surfaces of the plurality of micro-lens chips are coplanar.

In some embodiments, the solder terminal is a multi-layer structure, the multi-layer structure includes at least a core and an outer layer, and the outer layer directly or indirectly covers the core.

In some embodiments, the package structure further includes a lower redistribution layer, an active device, a dummy die, an encapsulation layer, an upper redistribution layer, and a connection element. The lower redistribution layer includes a first surface and a second surface opposite to the first surface. The active device is disposed on the first surface of the lower redistribution layer. The dummy die is disposed on the first surface of the lower redistribution layer. The dummy die is laterally adjacent to the active device. The encapsulation layer is disposed on the first surface of the lower redistribution layer, and is configured to encapsulate the active device and the dummy die. The upper redistribution layer is disposed on the encapsulation layer. The upper redistribution layer is electrically connected to the active device and the plurality of micro-lens chips. The connection element is disposed on the second surface of the lower redistribution layer. The connection element is a multi-layer structure, the multi-layer structure includes at least a core and an outer layer, and the outer layer directly or indirectly covers the core.

In comparison with the prior art, in the package structure and the manufacturing method thereof of the present disclosure, the plurality of micro-lens chips are encapsulated in the coplanar control layer, so that the plurality of micro-lens chips are coplanar. Specifically, each micro-lens chip includes a lens surface, a connection surface, and a terminal surface. In the present disclosure, the lens surfaces of the plurality of micro-lens chips are coplanar, the connection surfaces of the plurality of micro-lens chips are coplanar, and the terminal surfaces of the plurality of micro-lens chips are also coplanar. Therefore, the present disclosure ensures that the plurality of micro-lens chips in the package structure have a same focal plane.

### BRIEF DESCRIPTION OF DRAWINGS

FIG. 1 shows a schematic diagram of a package structure of a first embodiment of the present disclosure.

FIG. 2A to FIG. 2E show a series of cross-sectional views that illustrate manufacturing processes of a first substrate of FIG. 1.

FIG. 3A to FIG. 3I show a series of cross-sectional views that illustrate manufacturing processes of a second substrate of FIG. 1.

FIG. 4 shows a schematic diagram of a combination of the first substrate and the second substrate of the first embodiment of the present disclosure.

FIG. 5 shows a schematic diagram of a package structure of a second embodiment of the present disclosure.

FIG. 6 shows a top view of a package structure of a third embodiment of the present disclosure.

FIG. 7 shows a top view of a package structure of a fourth embodiment of the present disclosure.

FIG. 8 shows a partially enlarged view of a package structure of a fifth embodiment of the present disclosure.

FIG. 9 shows a partially enlarged view of a package structure of a sixth embodiment of the present disclosure.

### DETAILED DESCRIPTION

Embodiments will now be described more fully with reference to the accompanying drawings. However, the embodiments can be implemented in various forms and should not be construed as limited to the embodiments set forth herein. Rather, these embodiments are provided so that the present disclosure will be thorough and complete, and will fully convey the concept of the embodiments to those skilled in the art. The drawings are merely schematic illustrations of the present disclosure and are not necessarily drawn to scale. Same reference numerals in the drawings denote the same or similar parts, and thus their repeated descriptions will be omitted.

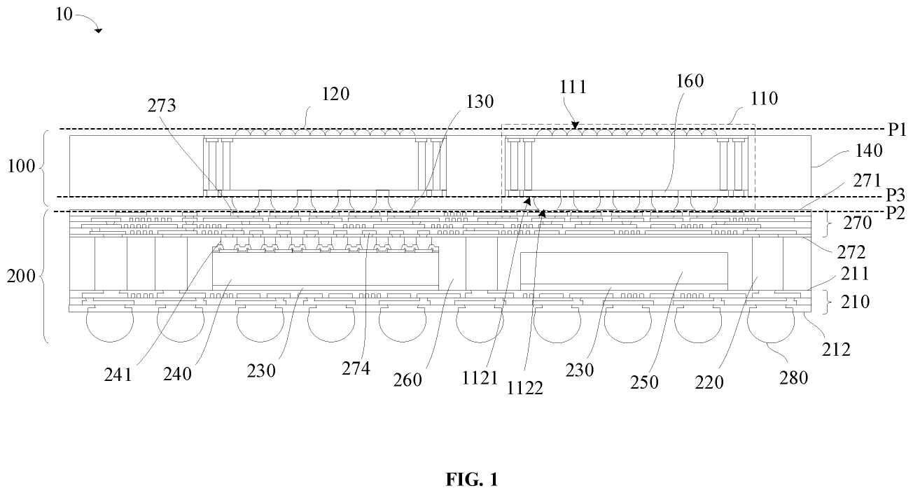

Referring to FIG. 1, which shows a schematic diagram of a package structure of a first embodiment of the present disclosure. The package structure 10 includes a first substrate 100 and a second substrate 200 that are stacked. The first substrate 100 includes two micro-lens chips 110 and a coplanar control layer 140. The micro-lens chips 110 are spaced apart. It should be understood that a number of micro-lens chips 110 is only for illustration, and the package structure 10 of the present disclosure may include more than two micro-lens chips 110, but is not limited thereto. Each micro-lens chip 110 includes a micro-lens array 120 and a plurality of solder terminals 130. The micro-lens array 120 and the plurality of solder terminals 130 are respectively disposed on opposite surfaces of the micro-lens chip 110. The micro-lens chips 110 include, but are not limited to, sensing elements, light emitting elements, LEDs, and the like. The micro-lens chips 110 can be configured for sensing, emitting light (display), transmitting and receiving signals, and so on.

As shown in FIG. 1, the coplanar control layer 140 is configured to encapsulate the two micro-lens chips 110 therein. At least one surface of each micro-lens chip 110 is exposed outside the coplanar control layer 140, and the at least one surface of each micro-lens chip 110 is coplanar. Specifically, each micro-lens chip 110 includes a lens surface 111, a connection surface 1121, and a terminal surface 1122. The micro-lens array 120 of each micro-lens chip 110 is exposed outside the coplanar control layer 140, and a horizontal plane formed by the outermost endpoints of a plurality of lenses of the micro-lens array 120 is the lens surface 111 of the micro-lens chip 110. In this embodiment, the two lens surfaces 111 of the two micro-lens chips 110 arranged at intervals are coplanar. For example, the two lens surfaces 111 of the two micro-lens chips 110 are located on a same first plane P1.

Furthermore, as shown in FIG. 1, the solder terminals 130 of each micro-lens chip 110 are exposed outside the coplanar control layer 140. A horizontal plane formed by the outermost endpoints of the plurality of solder terminals 130 is the terminal surface 1122 of the micro-lens chip 110. In this embodiment, the two terminal surfaces 1122 of the two micro-lens chips 110 arranged at intervals are coplanar. For example, the two terminal surfaces 1122 of the two micro-lens chips 110 are located on a same second plane P2.

On the other hand, as shown in FIG. 1, each micro-lens chip 110 further includes a plurality of connection terminals 160 connected to the plurality of solder terminals 130. Surfaces of the plurality of connection terminals 160 are exposed outside the coplanar control layer 140. Specifically, the connection terminal 160 is at least partially covered by dielectric material and exposes a portion of a surface to be connected to the solder terminal 130. A horizontal plane formed by exposed surfaces of the plurality of connection terminals 160 is the connection surface 1121 of the micro-lens chip 110. In this embodiment, the two connection surfaces 1121 of the two micro-lens chips 110 arranged at intervals are coplanar. For example, the two connection surfaces 1121 of the two micro-lens chips 110 are located on a same third plane P3.

In some embodiments, the micro-lens chip 110 may include through silicon vias (TSVs). The TSVs can be formed before bonding the micro-lens chip 110, or after molding. For example, if the TSVs are formed after molding, a manufacturing process is roughly as follows. First, the micro-lens chips 110 are bonded. Next, an over-molding process and a mold/chip back grinding process of are sequentially performed. Next, the TSVs, a redistribution layer, and a dielectric layer are sequentially formed. That is, the connection terminals 160 of the micro-lens chip 110 may be formed after the chip bonding process.

In some embodiments, the coplanar control layer 140 may include a molding compound formed by a molding process. Alternatively, the coplanar control layer 140 may be made of insulating materials such as epoxy resin or other suitable resins, including capillary underfill (CUF), non-conductive paste (NCP), non-conductive film (NCF), molding underfill (MUF), etc., but not limited thereof.

In some embodiments, spaces between the solder terminals 130 of the micro-lens chip 110 can be filled by CUF and NCF, so as to obtain better coplanarity and better reliability.

As shown in FIG. 1, the second substrate 200 of the package structure 10 includes a lower redistribution layer (RDL) 210, a first conductive pillar 220, an adhesive layer 230, an active device 240, a dummy die 250, an encapsulation layer 260, an upper redistribution layer 270, and a connection element 280.

As shown in FIG. 1, the lower redistribution layer 210 includes a first surface 211 and a second surface 212. The lower redistribution layer 210 includes a plurality of connection pads formed on both the first surface 211 and the second surface 212. The lower redistribution layer 210 are provided with wires. The lower redistribution layer 210 also includes dielectric material, and the connection pads and the wires are embedded in the dielectric material. It should be noted that the connection pads on the second surface 212 will be nearly coplanar with the surrounding dielectric material. Moreover, the first surface 211 of the lower redistribution layer 210 is a concave-convex surface. The connection pads on the first surface 211 are relatively recessed from the surrounding dielectric material. Specifically, the dielectric material on the first surface 211 has a plurality of openings exposing the connection pads. The wires are configured to connect the connection pads on the first surface 211 and the connection pads on the second surface 212. The lower redistribution layer 210 is electrically connected to a plurality of first conductive pillars 220 through the corresponding connection pads on the first surface 211, and the lower redistribution layer 210 is electrically connected to a plurality of connection elements 280 through the corresponding connection pads on the second surface 212. In this embodiment, a number of the first conductive pillars 220 is four, but not limited to this. The first conductive pillars 220 can be made of copper, aluminum, tin, gold, silver, or a combination of the above. Furthermore, the connection elements 280 can be formed by using a ball-mounting process, a plating process, or other suitable processes. In some embodiments, the connection element 280 is a solder ball formed by the ball-mounting process, thereby reducing a manufacturing cost and improving manufacturing efficiency. It should be understood that, according to design requirements, the connection element 280 may adopt other possible materials and shapes, and is not limited thereto. Alternatively, a bonding force between the connection element 280 and the corresponding connection pad of the lower redistribution layer 210 is enhanced by using a soldering process and a reflow process.

As shown in FIG. 1, the adhesive layer 230 is disposed on the first surface 211 of the lower redistribution layer 210, and the active device 240 and the dummy die 250 are disposed on the adhesive layer 230. The active device 240 and the dummy die 250 are bonded to the lower redistribution layer 210 through the adhesive layer 230. Specifically, the adhesive layer 230 includes a plurality of adhesive units, and the plurality of adhesive units are arranged on the first surface 211 of the lower redistribution layer 210. The active device 240 is arranged corresponding to one of the adhesive units, and the dummy die 250 is arranged corresponding to another one of the adhesive units. The active device 240 and the dummy die 250 are bonded to the lower redistribution layer 210 through the adhesive layer 230. Preferably, the adhesive layer 230 may be a die attach film (DAF). The adhesive layer 230 can effectively enhance the stability of the active device 240 and the dummy die 250, thereby preventing the active device 240 and the dummy die 250 from being displaced or falling off during subsequent processes. It should be noted that the active device 240 and the dummy die 250 are laterally adjacent to each other, and both are disposed at the same or approximately the same level. In addition, the active device 240 is formed with a plurality of connection pads and a plurality of second conductive pillars 241 on a surface away from the adhesive layer 230. The second conductive pillars 241 can be made of copper, aluminum, tin, gold, silver, or a combination of the above.

As shown in FIG. 1, the encapsulation layer 260 is disposed on the first surface 211 of the lower redistribution layer 210, the active device 240, and the dummy die 250. The encapsulation layer 260 is configured to encapsulate the active device 240 and the dummy die 250. Specifically, the encapsulation layer 260 encapsulates the first surface 211 of the lower redistribution layer 210 and elements (the first conductive pillars 220, the active device 240, and the dummy die 250) disposed thereon, and the encapsulation layer 260 fills spaces between the second conductive pillars 241 of the active device 240. The encapsulation layer 260 only exposes corresponding surfaces of the first conductive pillars 220 and the second conductive pillars 241 for electrical connection with subsequently formed elements. In some embodiments, the encapsulation layer 260 may include a molding compound formed by a molding process. Alternatively, the encapsulation layer 260 may be made of insulating materials such as epoxy resin or other suitable resins, including: capillary underfill (CUF), non-conductive paste (NCP), non-conductive film (NCF), and molded underfill (MUF). In some embodiments, better coplanarity and better reliability can be achieved by filling spaces between the elements (the first conductive pillars 220, the active device 240, and the dummy die 250) with the aforementioned materials.

As shown in FIG. 1, in this embodiment, the active device 240 is a functional chip, such as a controller chip. The dummy die 250 is a non-functional chip, such as a bare silicon chip. That is, the dummy die 250 is, for example, a semiconductor carrier that is similar in shape or appearance to a chip but does not have an in-chip active device. In the package structure 10, the dummy die 250 is electrically isolated from other elements (such as the lower redistribution layer 210, the active device 240, etc.). In the present disclosure, by encapsulating the dummy die 250 in the same encapsulation layer 260 as the active device 240 and the first conductive pillars 220, the material usage of the encapsulation layer 260 can be reduced. On the other hand, expansion coefficients of the encapsulation layer 260 and the elements (the first conductive pillar 220, the active device 240, and the dummy die 250) are different. By arranging the dummy die 250 on an adjacent side of the active device 240, the warpage of the second substrate 200 caused by a large amount of material of the encapsulation layer 260 on the side of the active device 240 is prevented.

As shown in FIG. 1, the upper redistribution layer 270 is disposed on a surface of the encapsulation layer 260 away from the lower redistribution layer 210. The upper redistribution layer 270 includes a first surface 271 and a second surface 272 opposite to the first surface 271. The first surface 271 and the second surface 272 of the upper redistribution layer 270 are both formed with a plurality of connection pads 273/274, and the upper redistribution layer 270 is internally provided with wires, which are configured to connect the connection pads 273 on the first surface 271 and the connection pads 274 on the second surface 272. The upper redistribution layer 270 also includes dielectric material, and the connection pads 273/274 and the wires are embedded in the dielectric material. It should be noted that the first surface 271 and the second surface 272 are concave-convex surfaces. The connection pads 273 on the first surface 271 are relatively recessed from the surrounding dielectric material, and the connection pads 274 on the second surface 272 are also relatively recessed from the surrounding dielectric material. Specifically, the dielectric material on the first surface 271 has a plurality of openings exposing the corresponding connection pads 273, and the dielectric material on the second surface 272 also has a plurality of openings exposing the corresponding connection pads 274. The upper redistribution layer 270 is electrically connected to the second conductive pillars 241 of the active device 240 through the corresponding connection pads 274 on the second surface 272. In practical applications, there is a via between the connection pad 274 and the second conductive pillar 241. Thus, the upper redistribution layer 270 may be electrically connected to the second conductive pillars 241 through the connection pads 274 and the vias. Furthermore, the upper redistribution layer 270 is also electrically connected to the first conductive pillars 220 through the corresponding connection pads 274 on the second surface 272.

In this embodiment, the dummy die 250 is not in contact with the second surface 272 of the upper redistribution layer 270. However, in some embodiments, the dummy die 250 may be designed to be in contact with the second surface 272 of the upper redistribution layer 270. It should be noted that regardless of whether the dummy die 250 is in contact with the upper redistribution layer 270, the dummy die 250 is configured to be electrically isolated from the upper redistribution layer 270.

In this embodiment, the electrical connection between the active device 240 and the upper redistribution layer 270 is realized through the second conductive pillars 241, and problems of wire breakage and low reliability are prevented from being cracked at a bonding interface between a low-k material and the active device 240 due to externally applied stress or internal stress in the process.

In the package structure 10 of the present disclosure, a multi-chip three-dimensional package with a miniaturized and compact design is realized by the lower redistribution layer 210 and the upper redistribution layer 270 under a condition of conforming to a package width. Thus, more design flexibility and freedom are provided for the application of the package structure 10 of the present disclosure in high-end products.

As shown in FIG. 1, the first substrate 100 is stacked on a surface of the second substrate 200 away from the lower redistribution layer 210, and the upper redistribution layer 270 is also electrically connected to the plurality of solder terminals 130 of the two micro-lens chips 110 through the corresponding connection pads 273 on the first surface 271. That is, the active device 240 is communicatively connected to the micro-lens chips 110 through the upper redistribution layer 270, and the micro-lens chips 110 can also transmit signals to the lower redistribution layer 210 through the upper redistribution layer 270, and further fan out the signals through the connection elements 280. In this embodiment, by directly connecting the solder terminals 130 of the micro-lens chips 110 and the upper redistribution layer 270, a signal transmission path is shortened to the greatest extent, thereby preventing signal loss. Specifically, the TSVs in the micro-lens chips 110 realize short-path signal transmission, thereby reducing signal loss.

In some embodiments, the package structure 10 also includes a protective cover. The protective cover is disposed on a surface of the coplanar control layer 140 close to the micro-lens arrays 120, and the protective cover covers the micro-lens arrays 120 of the micro-lens chips 110 to prevent the micro-lens arrays 120 from being damaged during manufacturing or transportation.

In this embodiment, the plurality of micro-lens chips 110 are encapsulated therein by the coplanar control layer 140, so that the lens surfaces 111 of the plurality of micro-lens chips 110 are coplanar, and the terminal surfaces 1122 of the plurality of micro-lens chips 110 are also coplanar. On the other hand, in the prior art, micro-lens chips need to be stacked individually on a redistribution layer, then implement underfill to protect the solder terminals, which results in a height difference between the plurality of micro-lens chips, and the plurality of micro-lens chips thus have different focal planes, which reduces an optical performance of the product. Compared with the prior art, in the present disclosure, the plurality of micro-lens chips 110 are encapsulated in the coplanar control layer 140, and then the plurality of micro-lens chips 110 together with the coplanar control layer 140 are disposed on the second substrate 200. It is prevented that a height difference between the plurality of micro-lens chips 110 caused by stacking the micro-lens chips 110 one by one. Moreover, it is ensured that the plurality of micro-lens chips in the package structure have a same focal plane.

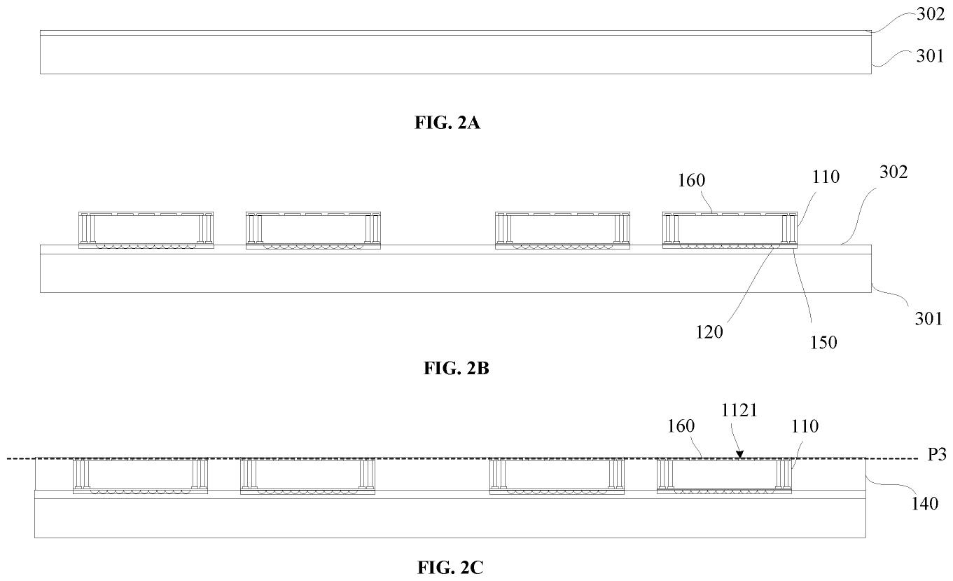

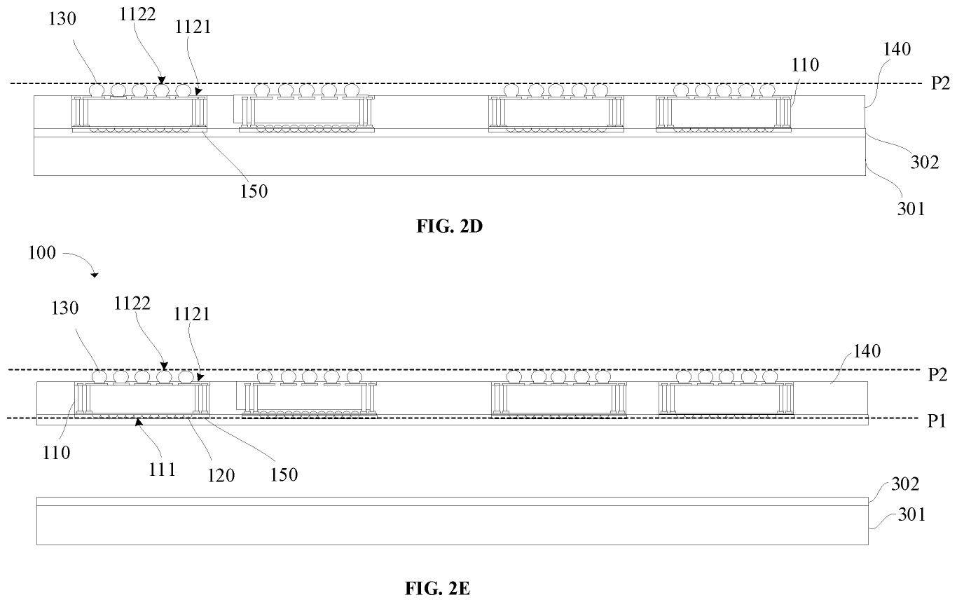

Referring to FIG. 2A to FIG. 2E, which show a series of cross-sectional views that illustrate manufacturing processes of a first substrate of FIG. 1. First, as shown in FIG. 2A, a carrier 301 is provided, and a separation layer 302 is formed on a surface of the carrier 301. The carrier 301 can provide good support for components formed above it to avoid a risk of structural deformation in subsequent steps. On the other hand, the separation layer 302 is configured to separate a subsequently formed film layer from the surface of the carrier 301. In addition, the separation layer 302 can also provide sufficient bonding force (through adhesion and/or other bonding force) between the carrier 301 and the subsequently formed film layer, so that the subsequent film layer can be formed successfully. In some embodiments, the separation layer 302 may include two layers. One is a release layer, and the other one is an adhesive layer. The release layer is directly in contact with the carrier 301 for subsequent debonding of the carrier 301. The adhesive layer is used to bond the micro-lens chips 110 to the carrier 301.

As shown in FIG. 2B, a plurality of micro-lens chips 110 arranged at intervals are bonded to the separation layer 302. In this embodiment, a number of the micro-lens chips 110 is four, but not limited to this. Each micro-lens chip 110 includes a micro-lens array 120 and a plurality of connection terminals 160. The micro-lens array 120 and the plurality of connection terminals 160 are respectively disposed on opposite surfaces of the micro-lens chip 110.

Alternatively, before the step of bonding the micro-lens chips 110 to the separation layer 302, the manufacturing method further includes: forming a protective film 150 on each of the micro-lens chips 110, and the protective film 150 covers the micro-lens array 120. Also, when the micro-lens chip 110 is bonded to the separation layer 302, the micro-lens array 120 of the micro-lens chip 110 is disposed on the separation layer 302 together with the protective film 150, and the connection terminals 160 of the micro-lens chip 110 are arranged on a side away from the separation layer 302.

In some embodiments, the micro-lens chip 110 may include through silicon vias (TSVs). The TSVs can be formed before bonding the micro-lens chip 110, or after molding. For example, if the TSVs are formed after molding, a manufacturing process is roughly as follows. First, the micro-lens chips 110 are bonded. Next, an over-molding process and a mold/chip back grinding process of are sequentially performed. Next, the TSVs, a redistribution layer, and a dielectric layer are sequentially formed. That is, the connection terminals 160 of the micro-lens chip 110 may be formed after the chip bonding process.

As shown in FIG. 2C, after the plurality of micro-lens chips 110 are arranged on the separation layer 302 at intervals, the coplanar control layer 140 is formed on the separation layer 302. The coplanar control layer 140 is configured to encapsulate the plurality of micro-lens chips 110 therein. In this step, the coplanar control layer 140 may include a molding compound formed by a molding process. Alternatively, the coplanar control layer 140 may be made of insulating materials such as epoxy resin or other suitable resins, including: capillary underfill (CUF), non-conductive paste (NCP), non-conductive film (NCF), and molded underfill (MUF). In some embodiments, better coplanarity and better reliability can be obtained by filling spaces between solder terminals 130 of the micro-lens chip 110 with the CUF and the NCF.

As shown in FIG. 2C, at least one surface of each micro-lens chip 110 is exposed outside a coplanar control layer 140, and the at least one surface of each micro-lens chip 110 is coplanar. Specifically, the plurality of connection terminals 160 of each micro-lens chip 110 are exposed outside the coplanar control layer 140. Each micro-lens chip 110 includes a connection surface 1121, and a horizontal plane formed by the exposed surfaces of the plurality of connection terminals 160 is the connection surface 1121 of the micro-lens chip 110. In practical applications, the connection terminal 160 is at least partially covered by dielectric material and exposes a portion of a surface, i.e., the connection surface 1121. In other words, the connection surface 1121 may be relatively recessed from a surface of the surrounding dielectric material. A plurality of the connection surfaces 1121 of the plurality of micro-lens chips 110 arranged at intervals are coplanar. For example, the plurality of connection surfaces 1121 of the plurality of micro-lens chips 110 are located on a same third plane P3.

As shown in FIG. 2D, after the coplanar control layer 140 is removed, the solder terminals 130 of each micro-lens chip 110 are formed. Specifically, in each micro-lens chip 110, a plurality of solder terminals 130 are connected to the plurality of connection terminals 160. In this embodiment, at least one surface of each micro-lens chip 110 is exposed outside the coplanar control layer 140, and the at least one surface of each micro-lens chip 110 is coplanar. Specifically, the plurality of solder terminals 130 of each micro-lens chip 110 are exposed outside the coplanar control layer 140. Each micro-lens chip 110 further includes a terminal surface 1122, and a horizontal plane formed by the outermost endpoints of the plurality of solder terminals 130 is the terminal surface 1122 of the micro-lens chip 110. A plurality of the terminal surfaces 1122 of the plurality of micro-lens chips 110 arranged at intervals are coplanar. For example, the plurality of terminal surfaces 1122 of the plurality of micro-lens chips 110 are located on a same second plane P2.

As shown in FIG. 2E, after the solder terminals 130 are formed, the carrier 301 is removed by the separation layer 302. After the step of removing the carrier 301, the manufacturing method further includes: removing the protective film 150. It is understood that the removal of the carrier 301 and the removal of the protective film 150 may not be performed consecutively. For example, the protective film 150 is removed after the first substrate 100 and the second substrate 200 are combined.

As shown in FIG. 2E, at least one surface of each micro-lens chip 110 is exposed outside the coplanar control layer 140, and the at least one surface of each micro-lens chip 110 is coplanar. Specifically, the micro-lens array 120 of each micro-lens chip 110 is exposed outside the coplanar control layer 140. Each micro-lens chip 110 further includes a lens surface 111, and a horizontal plane formed by the outermost endpoints of a plurality of lenses of the micro-lens array 120 is the lens surface 111 of the micro-lens chip 110. A plurality of the lens surfaces 111 of the plurality of micro-lens chips 110 arranged at intervals are coplanar. For example, the plurality of lens surfaces 111 of the plurality of micro-lens chips 110 are located on a same first plane P1.

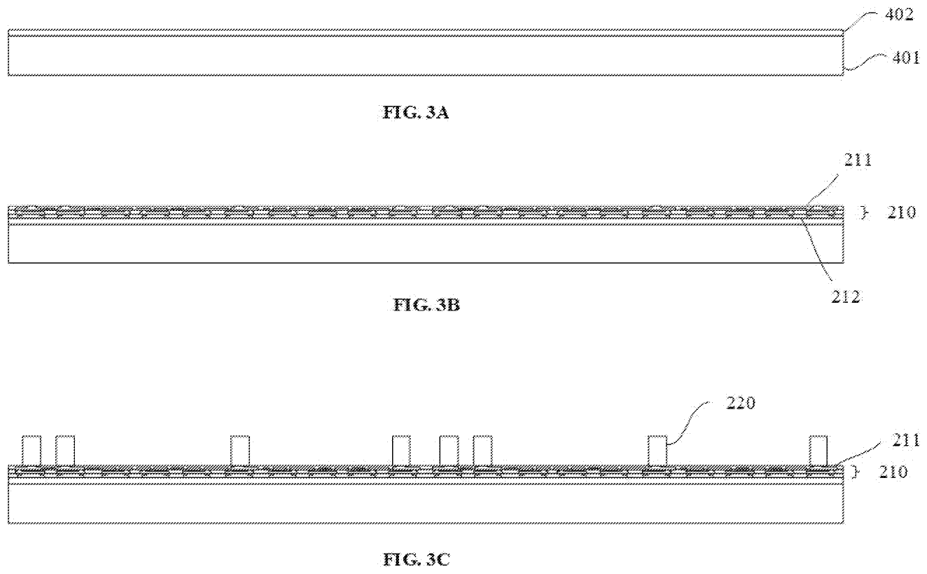

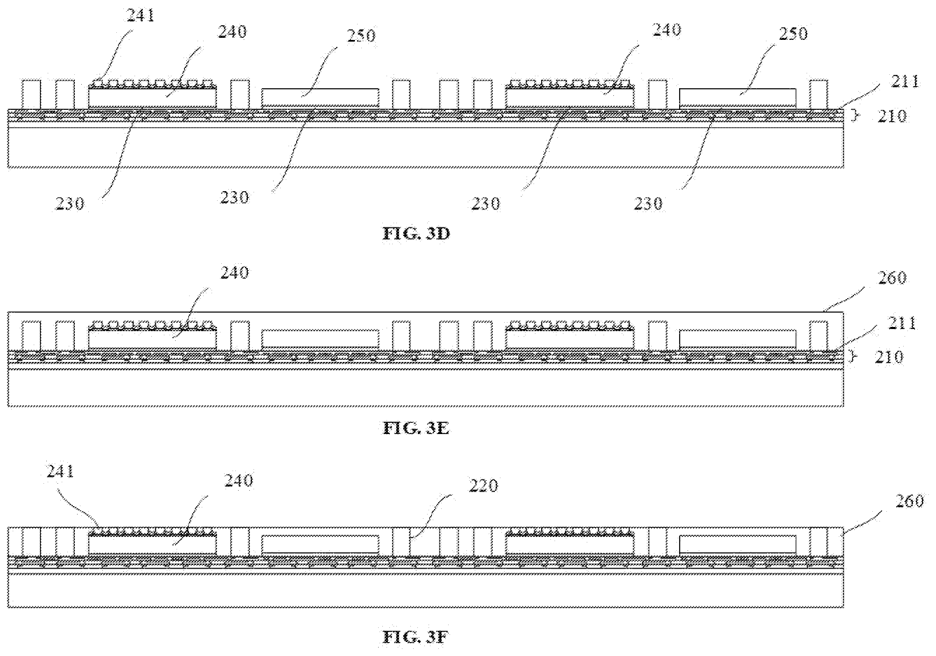

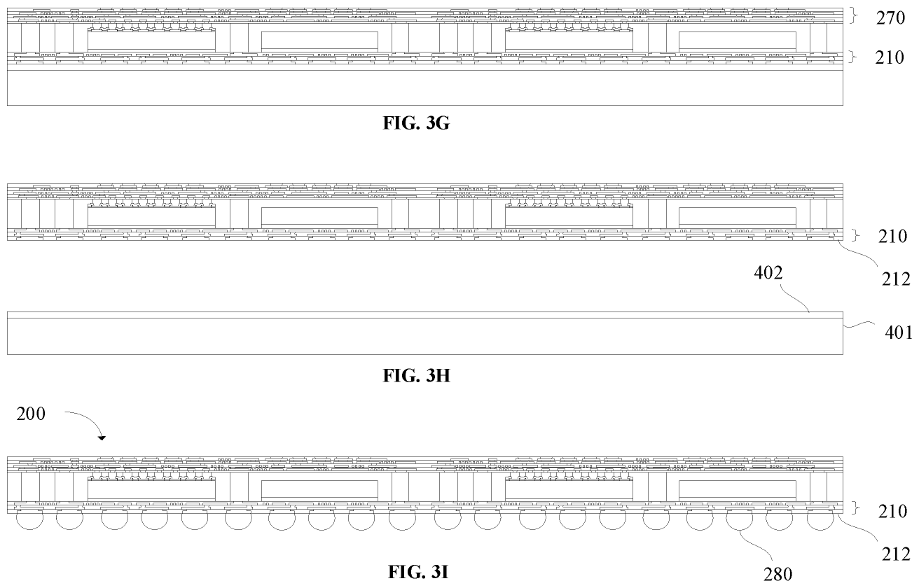

Referring to FIG. 3A to FIG. 3I, which show a series of cross-sectional views that illustrate manufacturing processes of a second substrate of FIG. 1. First, as shown in FIG. 3A, a carrier 401 is provided, and a separation layer 402 is formed on a surface of the carrier 401. The carrier 401 can provide good support for components formed above it to avoid a risk of structural deformation in subsequent steps. On the other hand, the separation layer 402 is configured to separate a subsequently formed film layer from the surface of the carrier 401. In addition, the separation layer 402 can also provide sufficient bonding force (through adhesion and/or other bonding force) between the carrier 401 and the subsequently formed film layer, so that the subsequent film layer can be successfully formed.

As shown in FIG. 3B, a lower redistribution layer 210 is formed on a surface of the separation layer 402 away from the carrier 401. The lower redistribution layer 210 includes a first surface 211 and a second surface 212 opposite to the first surface 211. The lower redistribution layer 210 includes a plurality of connection pads formed on both the first surface 211 and the second surface 212. The lower redistribution layer 210 are provided with wires. The lower redistribution layer 210 also includes dielectric material, and the connection pads and the wires are embedded in the dielectric material. It should be noted that the connection pads on the second surface 212 will be nearly coplanar with the surrounding dielectric material. Moreover, the first surface 211 of the lower redistribution layer 210 is a concave-convex surface. The connection pads on the first surface 211 are relatively recessed from the surrounding dielectric material. Specifically, the dielectric material on the first surface 211 has a plurality of openings exposing the connection pads. A specific structure of the lower redistribution layer 210 is referred to above, and will not be repeated here. Alternatively, the lower redistribution layer 210 may be formed by a photolithography process.

As shown in FIG. 3C, after the lower redistribution layer 210 is formed, a plurality of first conductive pillars 220 are formed on the first surface 211 of the lower redistribution layer 210 away from the carrier 401. Alternatively, the first conductive pillar 220 can be formed by electroplating.

As shown in FIG. 3D, after the first conductive pillars 220 are formed, a plurality of active devices 240 and a plurality of dummy dies 250 are arranged on the first surface 211 of the lower redistribution layer 210 away from the separation layer 402. The active devices 240 and the dummy dies 250 are laterally adjacent to each other, and are bonded to the lower redistribution layer 210 through the adhesive layer 230. For example, firstly, an adhesive layer 230 is disposed on one surface of each active device 240 and each dummy die 250, and then the active devices 240 and the dummy dies 250 are bonded together on the first surface 211 of the lower redistribution layer 210 through the adhesive layer 230. For another example, in some embodiments, an adhesive layer 230 may be formed on the first surface 211 of the lower redistribution layer 210 away from the separation layer 402 first, and then a plurality of active devices 240 and a plurality of dummy dies 250 may be formed on the surface of the adhesive layer 230 away from the lower redistribution layer 210. It should be understood that the adhesive layer 230 is first bonded to the active devices 240 and the dummy dies 250 and then the subsequent process is performed, or the adhesive layer 230 is first bonded to the lower redistribution layer 210 and then the subsequent process is performed, which is not limited herein.

As shown in FIG. 3D, corresponding second conductive pillars 241 are formed on a surface of the active device 240 away from the lower redistribution layer 210. Specific structures of the adhesive layer 230, the active devices 240, the dummy dies 250, and the second conductive pillars 241 can be referred to above, and will not be repeated here.

As shown in FIG. 3E, an encapsulation layer 260 is formed on the first surface 211 of the lower redistribution layer 210. The encapsulation layer 260 is configured to encapsulate the active devices 240 and the dummy dies 250. In this step, the encapsulation layer 260 completely covers the surface of the lower redistribution layer 210 and all the surfaces of the active devices 240 and the dummy dies 250 to encapsulate the active devices 240 and the dummy dies 250. In some embodiments, the encapsulation layer 260 may include a molding compound formed by a molding process. Alternatively, the encapsulation layer 260 may be formed of an insulating material such as epoxy resin or other suitable resins.

As shown in FIG. 3F, a thinning process is applied to the encapsulation layer 260 to reduce a thickness of the encapsulation layer 260 and expose corresponding surfaces of the first conductive pillars 220 and the second conductive pillars 241 of the active devices 240 for electrical connection with subsequently formed components. Alternatively, the thinning process can be performed by using a grinder.

As shown in FIG. 3G, an upper redistribution layer 270 is formed on a surface of the encapsulation layer 260 away from the lower redistribution layer 210. A specific structure of the upper redistribution layer 270 is referred to above, and will not be repeated here. Alternatively, the upper redistribution layer 270 may be formed by a photolithography process.

As shown in FIG. 3H, the carrier 401 is separated from the lower redistribution layer 210 by the separation layer 402.

As shown in FIG. 3I, a plurality of connection elements 280 are formed on the second surface 212 of the lower redistribution layer 210. The connection elements 280 may be formed by using a ball-mounting process, a plating process, or other suitable processes. In some embodiments, the connection element 280 is a solder ball formed by a ball-mounting process, thereby reducing manufacturing cost and improving manufacturing efficiency. It should be understood that, according to design requirements, the connection element 280 may adopt other possible materials and shapes, and is not limited thereto. Alternatively, a bonding force between the connection elements 280 and the corresponding connection pads of the lower redistribution layer 210 is enhanced by a soldering process and a reflow process.

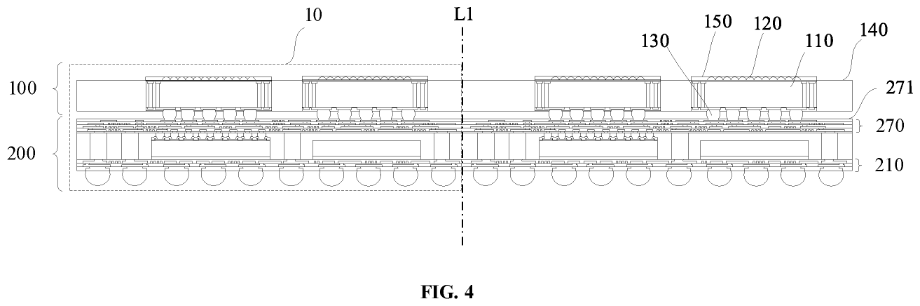

Referring to FIG. 4, which shows a schematic diagram of a combination of the first substrate and the second substrate of the first embodiment of the present disclosure. The first substrate 100 can be manufactured according to the steps corresponding to FIGS. 2A to 2E, and the second substrate 200 can be manufactured according to the steps corresponding to FIGS. 3A to 3I. As shown in FIG. 4, the above-mentioned first substrate 100 is stacked on a surface of the second substrate 200 away from the lower redistribution layer 210, and the plurality of micro-lens chips 110 and the coplanar control layer 140 are assembled with the upper redistribution layer 270 together. The upper redistribution layer 270 is electrically connected to the plurality of solder terminals 130 of the plurality of micro-lens chips 110 through the connection pads on the first surface 271.

As shown in FIG. 4, the first substrate 100 and the second substrate 200 are assembled and cut along a cutting line L1 to form a plurality of independent package structures 10. Alternatively, the above-mentioned cutting step can be realized by a cutting machine. It should be understood that the sequence of performing the assembling step and the cutting step of the first substrate 100 and the second substrate 200 is optional, for example, assembling first and then cutting, or first cutting and then assembling, but not limited thereto. For example, in this embodiment, by assembling the first substrate 100 and the second substrate 200 before cutting, side surfaces of the first substrate 100 and the second substrate 200 are ensured to be flush, and no additional processing steps are required to process the side surfaces of the first substrate 100 and the second substrate 200. Furthermore, in this embodiment, only one cutting process is needed to complete the division of the package structures 10, which effectively improves the production efficiency, and upper and lower substrates of the package structure 10 are prevented from being displaced or shifted. For another example, in some embodiments, the first substrate and the second substrate can be separately cut into small units, and then the small units are combined to form the package structure. In this embodiment, by adopting two cutting steps to cut the two substrates respectively, the machining accuracy during cutting can be ensured and the production difficulty can be reduced.

As shown in FIG. 4, in this embodiment, the coplanar control layer 140 encapsulates the plurality of micro-lens chips 110 therein, so that the lens surfaces 111 of the plurality of micro-lens chips 110 are coplanar, and a plurality of the micro-lens chips 110 are coplanar. The terminal surface 1122 is also coplanar. On the other hand, in the prior art, micro-lens chips are connected to an upper redistribution layer one by one, and then underfill material is filled between the solder terminals to protect the solder terminals of the plurality of micro-lens chips, which results in a height difference between the plurality of micro-lens chips, and the plurality of micro-lens chips thus have different focal planes, which reduces an optical performance of the product. Compared with the prior art, in the present disclosure, the plurality of micro-lens chips 110 are encapsulated in the coplanar control layer 140, and then the plurality of micro-lens chips 110 together with the coplanar control layer 140 are disposed on the second substrate 200. It is prevented that a height difference between the plurality of micro-lens chips 110 caused by stacking the micro-lens chips 110 one by one. Moreover, it is ensured that the plurality of micro-lens chips in the package structure have a same focal plane.

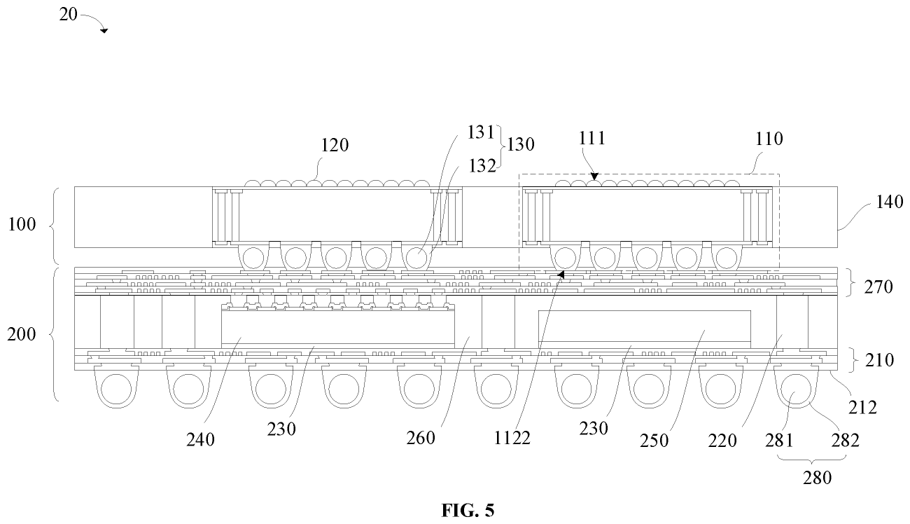

Referring to FIG. 5, which shows a schematic diagram of a package structure of a second embodiment of the present disclosure. The package structure 20 includes a first substrate 100 and a second substrate 200 which are stacked. The first substrate 100 includes two micro-lens chips 110 arranged at intervals and a coplanar control layer 140. It should be noted that the number of micro-lens chips 110 is only for illustration, and the package structure 20 of the present disclosure may include more than two micro-lens chips 110, and is not limited thereto. Each micro-lens chip 110 includes a micro-lens array 120 and a plurality of solder terminals 130. The micro-lens array 120 and the plurality of solder terminals 130 are respectively disposed on opposite surfaces of the micro-lens chip 110. The coplanar control layer 140 is configured to encapsulate the two micro-lens chips 110 therein. The second substrate 200 of the package structure 20 includes a lower redistribution layer 210, first conductive pillars 220, an adhesive layer 230, an active device 240, a dummy die 250, an encapsulation layer 260, an upper redistribution layer 270, and connection elements 280. The package structure 20 of the second embodiment has substantially the same as the package structure 10 of the first embodiment, a difference between the two is that the solder terminals 130 of the micro-lens chip 110 and the connection elements 280 of the second substrate 200 are multi-layer structures.

As shown in FIG. 5, in this embodiment, the solder terminals 130 and the connection elements 280 are designed as a double-layer structure. The double-layer structure includes at least a core and an outer layer, and the outer layer directly covers the core. In this embodiment, the core can be made of any known non-conductive or conductive material, such as plastic, polymers, copper, nickel, palladium, gold, titanium, silver, or alloys thereof, but preferably polymers or copper. The outer layer can be made of any known conductive material such as tin, silver, nickel, palladium, gold, titanium, copper, or alloys thereof.

Alternatively, in some embodiments, the solder terminals 130 and the connection elements 280 may include more than two layers, such as three layers, four layers, and the like. For example, each of the solder terminal 130 and the connection element 280 may include at least a core, a metal layer, and an outer layer. The metal layer is disposed between the core and the outer layer, this is, the outer layer indirectly covers the core. Specifically, the metal layer covers the core, and the outer layer surrounds the metal layer. The metal layer may include, for example, copper, nickel or other suitable conductive materials.

As shown in FIG. 5, the solder terminal 130 of the micro-lens chip 110 includes a first core 131 and a first outer layer 132, and the first outer layer 132 covers the first core 131. Furthermore, the connection element 280 of the second substrate 200 includes a second core 281 and a second outer layer 282, and the second outer layer 282 covers the second core 281. In this embodiment, the first core 131 of the solder terminal 130 and the second core 281 of the connection element 280 server as spacers to control stacking co-planarity. That is, a size of the solder terminal 130 can be better controlled by the multi-layer structure of the solder terminal 130, thereby ensuring that the plurality of terminal surfaces 1122 of the plurality of micro-lens chips 110 arranged at intervals have better coplanarity with each other. Similarly, the design of the multi-layer structure can also ensure that the connection element 280 formed on the second surface 212 of the lower redistribution layer 210 has better coplanarity. Furthermore, the first outer layer 132 of the solder terminal 130 and the second outer layer 282 of the connection element 280 are configured to make sure the bonding strength between top and bottom packages.

It should be noted that when the core is made of conductive material, such as copper, a melting point temperature of the core is higher than that of the outer layer, and a rigidity of the core is greater than that of the outer layer. Furthermore, when the core is made of non-conductive, such as polymers, the core will not melt under typical solder reflow processes/temperatures. Moreover, the polymer core is flexible, which ensures that the solder terminal 130 or the connection element 280 will not be collapsed or excessively deformed due to extrusion, thereby maintaining the height of the solder terminal 130 or the connection element 280. In the present disclosure, by adopting the above-mentioned multi-layer structure for the solder terminal 130 of the micro-lens chip 110 and the connection element 280 of the second substrate 200, it can not only resist mechanical shock and thermal fatigue, but also maintain good electrical conductivity.

It can be understood that, the package structure 20 of this embodiment can be formed by the above-mentioned manufacturing method, which will not be repeated here.

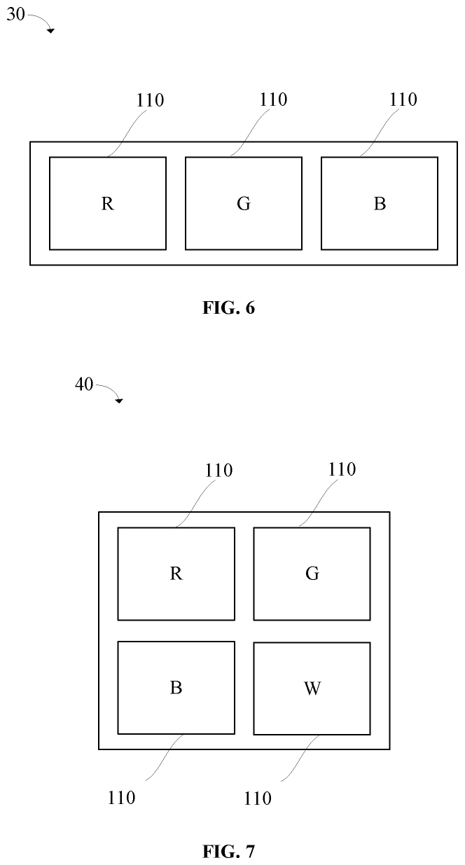

Referring to FIG. 6, which shows a top view of a package structure of a third embodiment of the present disclosure. A package structure 30 includes three micro-lens chips 110, and each micro-lens chip 110 serves as a color optical element, such as red optical element R, green optical element G, and blue optical element B. When viewed from the top view, the plurality of micro-lens chips 110 are arranged in a matrix. It should be noted that in the same package structure, the optical elements of different colors all have the same focal plane. A shape of the package structure can be square, rectangular, irregular (such as L-shape), etc. An arrangement sequence of color optical elements R/G/B can be adjusted as required.

Referring to FIG. 7, which shows a top view of a package structure of a fourth embodiment of the present disclosure. A package structure 40 includes four micro-lens chips 110, each of which serves as a color optical element, such as red optical element R, green optical element G, blue optical element B, and white optical element W. When viewed from the top view, the plurality of micro-lens chips 110 are arranged in a matrix. It should be noted that in the same package structure, the optical elements of different colors all have the same focal plane. A shape of the package structure can be square, rectangular, irregular (such as L-shape), etc. An arrangement sequence of color optical elements R/G/B/W can be adjusted as required.

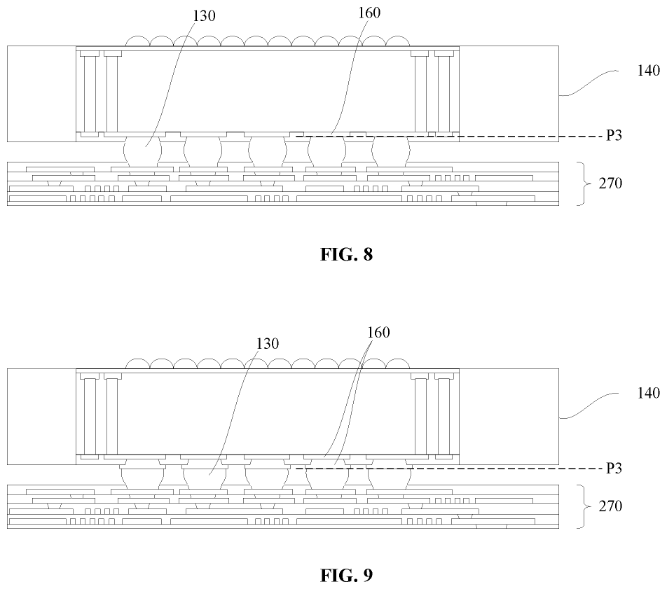

Referring to FIG. 8, which shows a partially enlarged view of a package structure of a fifth embodiment of the present disclosure. The package structure of the fifth embodiment is similar to the package structure of the first embodiment, the difference between them is that the third plane P3 of the packaging structure of the fifth embodiment is not on the same plane as a bottom surface (i.e., a surface facing the upper redistribution layer 270) of the coplanar control layer 140. Specifically, the connection terminal 160 is at least partially covered by dielectric material and exposes a portion of a surface to be connected to the solder terminal 130. The exposed surface of connection terminal 160 is relatively recessed from the bottom surface of the coplanar control layer 140. A horizontal plane formed by exposed surfaces of the plurality of connection terminals 160 is the connection surface of the micro-lens chip, and the connection surfaces of all micro-lens chips are located on the same third plane P3. As shown in FIG. 8, the third plane P3 is far away from the upper redistribution layer 270 relative to the bottom surface of the coplanar control layer 140.

Referring to FIG. 9, which shows a partially enlarged view of a package structure of a sixth embodiment of the present disclosure. The package structure of the sixth embodiment is similar to the package structure of the first embodiment, the difference between them is that the third plane P3 of the packaging structure of the sixth embodiment is not on the same plane as a bottom surface (i.e., a surface facing the upper redistribution layer 270) of the coplanar control layer 140. Specifically, the connection terminal 160 includes a metal wire embedded in dielectric material and a metal bump stacked on the metal wire. The metal bump of the connection terminal 160 protrudes relatively from the coplanar control layer 140. That is, an outer surface of connection terminal 160 protrudes relatively from the bottom surface of the coplanar control layer 140. A horizontal plane formed by outer surfaces of the plurality of connection terminals 160 is the connection surface of the micro-lens chip, and the connection surfaces of all micro-lens chips are located on the same third plane P3. As shown in FIG. 9, the third plane P9 is closer to the upper redistribution layer 270 relative to the bottom surface of the coplanar control layer 140.

In summary, in the package structure and the manufacturing method thereof of the present disclosure, the coplanar control layer encapsulates the plurality of micro-lens chips therein, so that the lens surfaces of the plurality of micro-lens chips are coplanar, and the terminal surfaces of the plurality of micro-lens chips are also coplanar. Therefore, the present disclosure ensures that the plurality of micro-lens chips in the package structure have the same focal plane. The same focal plane means that each micro-lens chip can display (illuminate) each color with well hybrid to form the good image. Furthermore, the size of the solder terminal can be better controlled by the multi-layer structure of the solder terminal, thereby ensuring that the plurality of terminal surfaces of the plurality of micro-lens chips arranged at intervals have better coplanar characteristics with each other.

The above descriptions are only specific embodiments of the present disclosure, but the protection scope of the present disclosure is not limited thereto. Any changes or substitutions that can be easily thought of by those skilled in the art within the technical scope disclosed in the present disclosure should be covered by the protection scope of the present disclosure. Therefore, the protection scope of the present disclosure should be subject to the protection scope of the claims.

What is claimed is:

1. A package structure, comprising:
a plurality of micro-lens chips arranged at intervals; and
a coplanar control layer configured to encapsulate the plurality of micro-lens chips therein, wherein at least one surface of each of the micro-lens chips is exposed outside the coplanar control layer, and the at least one surface of each of the micro-lens chips is coplanar.

2. The package structure according to claim 1, wherein each of the micro-lens chips comprises a micro-lens array, a plurality of the micro-lens arrays of the plurality of micro-lens chips are exposed outside the coplanar control layer, and a plurality of surfaces of the plurality of the micro-lens arrays are coplanar.

3. The package structure according to claim 1, wherein each of the micro-lens chips comprises solder terminals, a plurality of the solder terminals of the plurality of micro-lens chips are exposed outside the coplanar control layer, and a plurality of surfaces of the plurality of solder terminals are coplanar.

4. The package structure according to claim 3, wherein each of the micro-lens chips further comprises a plurality of connection terminals connected to the plurality of solder terminals, the plurality of connection terminals of each of the micro-lens chips are exposed outside the coplanar control layer, a horizontal plane formed by the plurality of connection terminals of each of the micro-lens chips is a connection surface of the micro-lens chip, and a plurality of the connection surfaces of the plurality of micro-lens chips are coplanar.

5. The package structure according to claim 3, wherein the solder terminal is a multi-layer structure, the multi-layer structure comprises at least a core and an outer layer, and the outer layer directly or indirectly covers the core.

6. The package structure according to claim 3, further comprising:
a lower redistribution layer comprising a first surface and a second surface opposite to the first surface;
an active device disposed on the first surface of the lower redistribution layer;
a dummy die disposed on the first surface of the lower redistribution layer, wherein the dummy die is laterally adjacent to the active device;
an encapsulation layer disposed on the first surface of the lower redistribution layer, and configured to encapsulate the active device and the dummy die; and
an upper redistribution layer disposed on the encapsulation layer, wherein the upper redistribution layer is electrically connected to the active device and the plurality of solder terminals of the plurality of micro-lens chips.

7. The package structure according to claim 6, further comprising a connection element disposed on the second surface of the lower redistribution layer, wherein the connection element is a multi-layer structure.

8. A manufacturing method of a package structure, comprising:
providing a carrier;
forming a separation layer on the carrier;
disposing a plurality of micro-lens chips arranged at intervals on the separation layer;
forming a coplanar control layer on the separation layer, wherein the coplanar control layer encapsulates the plurality of micro-lens chips therein; and
removing the carrier by the separation layer, wherein at least one surface of each of the micro-lens chips is exposed outside the coplanar control layer, and a plurality of the at least one surfaces of the plurality of micro-lens chips are coplanar.

9. The manufacturing method of the package structure according to claim 8, wherein each of the micro-lens chips comprises a micro-lens array, and before the plurality of micro-lens chips are disposed on the separation layer, the manufacturing method further comprises: forming a protective film on each of the micro-lens chips, and the protective film covers the micro-lens array; and
after removing the carrier, the manufacturing method further comprises: removing the protective film, wherein the plurality of micro-lens arrays of the plurality of micro-lens chips are exposed outside the coplanar control layer, and a plurality of surfaces of the plurality of micro-lens arrays are coplanar.

10. The manufacturing method of the package structure of claim 8, wherein before removing the carrier, the manufacturing method further comprises: forming solder terminals of each of the micro-lens chips, wherein a plurality of the solder terminals of the plurality of micro-lens chips are exposed outside the coplanar control layer, and a plurality of surfaces of the plurality of the solder terminals are coplanar.

11. The manufacturing method of the package structure of claim 10, wherein each of the micro-lens chips further comprises a plurality of connection terminals connected to the plurality of solder terminals, and the plurality of connection terminals of each of the micro-lens chips are exposed outside the coplanar control layer, a horizontal plane formed by the plurality of connection terminals of each of the micro-lens chips is a connection surface of the micro-lens chip, and a plurality of the connection surfaces of the plurality of micro-lens chips are coplanar.

12. The manufacturing method of the package structure of claim 10, wherein the solder terminal is a multi-layer structure, the multi-layer structure comprises a core and an outer layer, and the outer layer directly or indirectly covers the core.

13. The manufacturing method of the package structure of claim 10, further comprising:
forming a lower redistribution layer, wherein the lower redistribution layer comprises a first surface and a second surface opposite to the first surface;
forming an active device and a dummy die on the first surface of the lower redistribution layer, wherein the dummy die is laterally adjacent to the active device;
forming an encapsulation layer on the first surface of the lower redistribution layer, wherein the encapsulation layer is configured to encapsulate the active device and the dummy die;
forming an upper redistribution layer on the encapsulation layer, wherein the upper redistribution layer is electrically connected to the active device; and
assembling the plurality of micro-lens chips and the coplanar control layer with the upper redistribution layer, wherein the upper redistribution layer is electrically connected to the plurality of solder terminals of the plurality of micro-lens chips.

14. The manufacturing method of the package structure of claim 13, further comprising:
forming a connection element on the second surface of the lower redistribution layer, wherein the connection element is a multi-layer structure.

15. A package structure, comprising:
a plurality of micro-lens chips arranged at intervals; and
a coplanar control layer configured to encapsulate the plurality of micro-lens chips therein, wherein each of the micro-lens chips comprises a lens surface, a connection surface, and a terminal surface, and one of the lens surface, the connection surface, and the terminal surface of each of the micro-lens chips is coplanar.

16. The package structure according to claim 15, wherein each of the micro-lens chips comprises a micro-lens array, a plurality of the micro-lens arrays of the plurality of micro-lens chips are exposed outside the coplanar control layer, a horizontal plane formed by outermost endpoints of a plurality of lenses of the micro-lens array of each micro-lens chip is the lens surface of the micro-lens chip, and a plurality of the lens surfaces of the plurality of micro-lens chips are coplanar.

17. The package structure according to claim 15, wherein each of the micro-lens chips comprises solder terminals, a plurality of the solder terminals of the plurality of micro-lens chips are exposed outside the coplanar control layer, a horizontal plane formed by outermost endpoints of the plurality of solder terminals of each micro-lens chip is the terminal surface of the micro-lens chip, and a plurality of the terminal surfaces of the plurality of micro-lens chips are coplanar.

18. The package structure according to claim 17, wherein each of the micro-lens chips further comprises a plurality of connection terminals connected to the plurality of solder terminals, the plurality of connection terminals of each of the micro-lens chips are exposed outside the coplanar control layer, a horizontal plane formed by the plurality of connection terminals of each micro-lens chip is the connection surface of the micro-lens chip, and a plurality of the connection surfaces of the plurality of micro-lens chips are coplanar.

19. The package structure according to claim 17, wherein the solder terminal is a multi-layer structure, the multi-layer structure comprises at least a core and an outer layer, and the outer layer directly or indirectly covers the core.

20. The package structure according to claim 15, further comprising:
a lower redistribution layer comprising a first surface and a second surface opposite to the first surface;
an active device disposed on the first surface of the lower redistribution layer;
a dummy die disposed on the first surface of the lower redistribution layer, wherein the dummy die is laterally adjacent to the active device;
an encapsulation layer disposed on the first surface of the lower redistribution layer, and configured to encapsulate the active device and the dummy die;
an upper redistribution layer disposed on the encapsulation layer, wherein the upper redistribution layer is electrically connected to the active device and the plurality of micro-lens chips; and
a connection element disposed on the second surface of the lower redistribution layer, wherein the connection element is a multi-layer structure, the multi-layer structure comprises at least a core and an outer layer, and the outer layer directly or indirectly covers the core.
